(19) United States
(12) Patent Application Publication
(10) Pub. No.: US 2008/0090170 A1
(43) Pub. Date: Apr. 17, 2008

(54) PATTERN FORMING TEMPLATE AND PATTERN FORMING METHOD

(76) Inventor: Ikuo YONEDA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/866,538

(22) Filed: Oct. 3, 2007

(30) Foreign Application Priority Data
Oct. 4, 2006 (JP) 2006-273179

(51) Int. Cl. G03F 7/24; G03C 1/73

(52) U.S. Cl. 430/270.1; 430/322

(57) ABSTRACT

A pattern forming template used in a nano-imprinting method is disclosed. An imprint material layer formed of liquid having a photo-setting property is coated on a to-be-processed substrate. A pattern is transferred onto the imprint material layer by applying light to a surface on which the pattern is not formed from above the surface to cure the imprint material layer while a surface of the template on which the pattern having concave and convex portions is formed is kept in contact with the imprint material layer. Dummy grooves are formed in the template to absorb a surplus portion of the liquid on the imprint material layer.

### CROSS-REFERENCE TO RELATED APPLICATIONS

This application is based upon and claims the benefit of priority from prior Japanese Patent Application No. 2006-273179, filed Oct. 4, 2006, the entire contents of which are incorporated herein by reference.

### BACKGROUND OF THE INVENTION

1. Field of the Invention

This invention relates to the fine patterning technique in a manufacturing process for semiconductor devices and more particularly to a pattern forming template and pattern forming method in a nano-imprinting lithography method for performing a pattern transfer process with a patterned template kept in contact with or set close to a to-be-transferred substrate such as a wafer.

2. Description of the Related Art

In a manufacturing process for semiconductor elements, a nano-imprinting exposure method for transferring a template pattern of an original onto a to-be-transferred substrate has received much attention as the technology for simultaneously attaining mass production and formation of fine patterns of 100 nm or less.

The nano-imprinting method is a method for transferring a pattern onto a resist layer by pressing a template of an original on which a to-be-transferred pattern is formed onto the resist layer which is formed of an imprint material coated on the substrate and curing or hardening the resist layer. As the nano-imprinting method, a thermal imprinting method mainly using thermoplastic resist and a photo imprinting method using photo-setting resist are known (for example, refer to Jpn. Pat. Appln. KOKAI Publication Nos. 2003-77807, 2001-68411 and 2000-194142).

In the nano-imprinting method, since a pattern of a 3-dimensional form formed on the template can be transferred, for example, a pattern with a step form, lens form or the like can be transferred.

The flow of a pattern transfer process by the photo nano-imprinting method which is one type of the nano-imprinting method includes the following steps.

(1) Coating photo-setting resin which is an imprint material onto a to-be-processed substrate

(2) Aligning and pressing (contacting) the substrate with and against the template

(3) Resin curing by application of light

(4) Mold releasing and rinsing the template

(5) Removing remaining films by use of an anisotropic etching process mainly using oxygen plasma

As the method for coating the imprint material onto the wafer, a spin coating method and ink jet method are provided. In the spin coating method, the throughput can be enhanced, but it is necessary to pay much attention to the imprint material before application of light since the imprint material is liquid. Further, there occurs a problem that the efficiency of usage of the imprint material is low.

In the ink jet method, since a necessary and sufficient amount of imprint material for imprinting can be coated, the efficiency of usage of the imprint material is high. Further, unlike the spin coating method, the wafer on which the imprint material of “liquid” is set in an island form will not move between devices since the imprint material of only one shot (one pressing step by use of the template) is coated before imprinting in the imprinting apparatus.

However, it is desired to control the coating amount on the order of pico-liter in the imprint material coating process by the ink jet method. Therefore, generally, in the imprinting apparatus, the density of a pattern to be imprinted is read from GDS (mask pattern) data to control a jet amount. In spite of the above control process, a difference in the jet amount occurs and a coating amount will be varied in some cases. Therefore, there occurs a possibility that a surplus portion of the imprint material is pressed out to a boundary portion (dicing area) with a neighboring shot area. On the other hand, when a jet amount of the imprint material becomes insufficient, a “cushion” between the template and the wafer is eliminated, the template and wafer interfere with each other and dusts and faults will occur.

Therefore, it is required to develop a template, imprinting apparatus or imprint material coating method which is robust with respect to an imprint material coating process.

Further, since the imprint material before application of light is not so-called polymer, the volatility thereof is relatively high. Since it takes a longer time to coat the imprint material by the ink jet method in comparison with the spin coating method, the volatile amount of the imprint material becomes different in the wafer plane or shot plane between the first coated area and the last coated area. In this state, if the imprinting process is performed, the remaining film amount will become different. Since the remaining film etching process is performed after imprinting, the difference in the remaining film amount will give an influence to a variation in the dimensions or the like.

In the lithography process, the necessary height of a resist pattern is specified according to the requirement for processing (etching) a ground layer after formation of the resist pattern. For example, in the photolithography process, the height of the resist pattern after development can be determined mainly by the film thickness of a coated resist film. In this case, it is necessary to consider the fall of the resist pattern due to the surface tension at the development and drying time, but the requirement for processing the ground layer can be roughly satisfied.

However, in the nano-imprinting method, it is necessary to separate the solidified pattern and template from each other in the template separation step (4) described above. At this time, friction force corresponding to the adhered area of the pattern and template is applied between the pattern and the template. Since the tension strength of resin which forms the pattern becomes weaker as the pattern width becomes smaller, there occurs a possibility that faults of mold releasing the pattern from the ground layer and cutting off the pattern in the middle at the template separation time will occur in the pattern having the small pattern width and large film thickness, that is, a high aspect ratio.

In order to solve the above problem, it is necessary to suppress friction force at the template separation time and it is considered to suppress the friction force between the pattern and the template by forming a groove of a pattern to be formed on the template into a tapered form (taper off or taper down) or contracting the whole portion of the resin pattern at the solidifying time of photo-setting resin.

However, in the method of forming the groove into the tapered form, the tension resistance required at the initial time of the template separation step is not alleviated. Further, at the etching time of the remaining film and ground layer in the nano-imprinting process, deterioration in the pattern form and a variation in the dimension (CD: Critical Dimension) occur.

In addition, in the method of contracting the whole portion of the resin pattern, since the dimensional variation is large although the tension resistance required at the initial time of the template separation step is alleviated, it is necessary to form a template by previously taking the dimensional variation into consideration at the template forming time.

Therefore, it is desired to provide a nano-imprinting method and template which are robust with respect to the pattern of the high aspect ratio and less subject to deterioration in the form and variation in the dimension by improving the nano-imprint material and using a method for forming the adequate template structure.

### BRIEF SUMMARY OF THE INVENTION

A pattern forming template according to a first aspect of the present invention is a pattern forming template used in a nano-imprinting method for transferring a pattern of a device pattern formation having concave and convex portions onto an imprint material layer formed of liquid having a photo-setting property and coated on a to-be-processed substrate by applying light to a surface of the template on which the pattern is not formed from above the surface to cure the imprint material layer while a surface of the template on which the pattern is formed is kept in contact with the imprint material layer and includes a dummy groove which is different from the pattern.

A pattern forming method according to a second aspect of the present invention includes coating an imprint material layer formed of liquid having a photo-setting property by application of UV lights on a to-be-processed substrate, making the coated liquid in contact with a template on which a pattern having concave and convex portions and a dummy groove which is different from the pattern are formed, and applying UV lights to a surface of the template on which the pattern is not formed from above the surface to cure the liquid into resin and transferring the pattern onto the resin.

### BRIEF DESCRIPTION OF THE SEVERAL VIEWS OF THE DRAWING

FIG. 1 is a cross sectional view showing one manufacturing step of a pattern forming method according to a first embodiment of this invention;

FIG. 2 is a plan view showing the pattern arrangement of a surface of a template used in the first embodiment of this invention on which a pattern to be transferred is formed;

FIGS. 3A to 3D are plan views showing dummy pattern forms of the template used in the first embodiment of this invention;

FIG. 4 is a cross sectional view showing one manufacturing step of the pattern forming method according to the first embodiment following after the step of FIG. 1;

FIG. 5 is a cross sectional view showing one manufacturing step of a pattern forming method using the conventional template;

FIG. 6 is a cross sectional view showing one manufacturing step of the pattern forming method according to the first embodiment following after the step of FIG. 4;

FIG. 7 is a cross sectional view showing one manufacturing step of the pattern forming method according to the first embodiment following after the step of FIG. 6;

FIG. 8 is a plan view showing the arrangement of a light shielding film or semitransparent film of a different template used in the first embodiment;

FIG. 9 is a cross sectional view showing one manufacturing step of a pattern forming method according to a second embodiment of this invention;

FIG. 10 is a characteristic diagram showing the light intensity, polymerization degree and coefficient of contraction with respect to the depth from the surface of a photo nano-imprint material used in the pattern forming method according to the second embodiment of this invention;

FIG. 11 is a cross sectional view showing one manufacturing step of the pattern forming method according to the second embodiment following after the step of FIG. 9;

FIG. 12 is an enlarged cross sectional view showing one manufacturing step of the pattern forming method according to the second embodiment following after the step of FIG. 11;

FIG. 13 is a cross sectional view showing the state at the template mold releasing time when the conventional nano-imprint material is used;

FIG. 14 is a cross sectional view showing one manufacturing step of a pattern forming method according to a third embodiment of this invention;

FIG. 15 is a cross sectional view showing one manufacturing step of the pattern forming method according to the third embodiment following after the step of FIG. 14;

FIG. 16 is a schematic cross sectional view showing the configuration of a nano-imprinting apparatus according to a fourth embodiment of this invention; and

FIG. 17 is a flowchart showing the method of manufacturing semiconductor device according to a fifth embodiment of this invention.

### DETAILED DESCRIPTION OF THE INVENTION

### First Embodiment

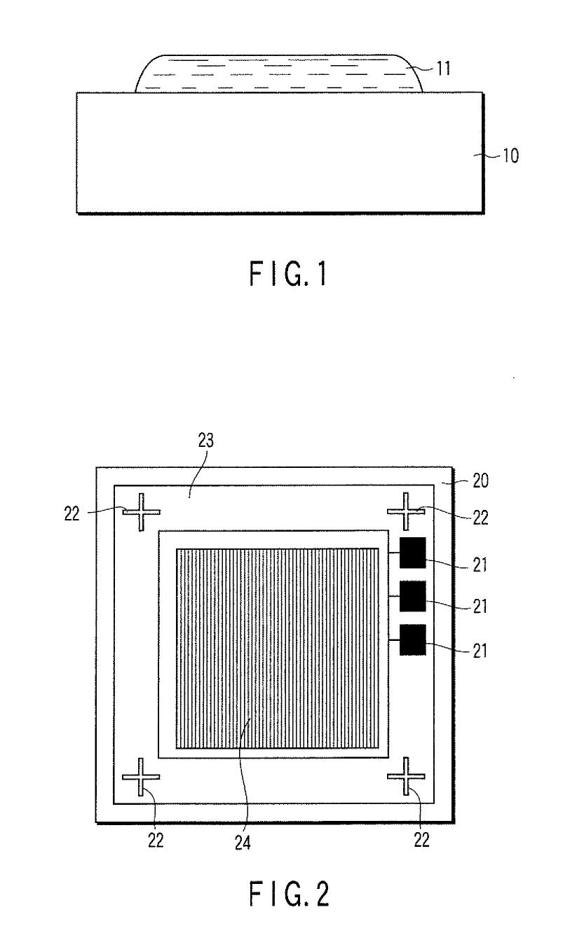

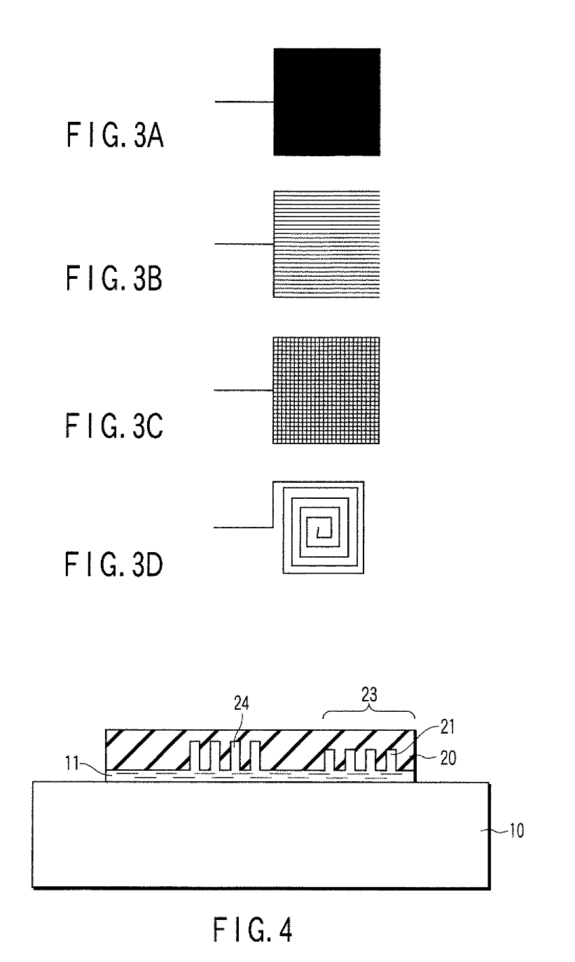

A pattern forming method by use of a photo nano-imprinting method according to a first embodiment of this invention is explained below with reference to FIG. 1, FIG. 2, FIGS. 3A to 3D, FIG. 4, and FIGS. 6 to 8.

First, a to-be-processed substrate 10 is prepared and a nano-imprint material 11 which is a photo-setting resin material of liquid is coated by one shot by use of an ink jet method as shown in the cross sectional view of FIG. 1.

As the to-be-processed substrate 10, a silicon substrate itself can be used or a substrate on which a mask formed of an organic film or an inter-level insulating film such as a silicon oxide film or low-k (low permittivity) film is formed can be used.

Next, a template 20 for nano-imprinting is prepared. For example, the template 20 is formed by forming a concavo-convex pattern on a fully transparent quartz substrate which is generally used for a photomask by plasma etching. The state of the pattern arrangement of the surface of the template 20 on which the pattern to be transferred is formed is shown in FIG. 2.

In the central portion of the template 20, for example, concave and convex portions of a main pattern 4 which is a device pattern of lines-and-spaces are formed. In a dicing area 23 on the peripheral portion used as a marginal portion for cutting-off of the chip, dummy patterns 21 which are dummy grooves are formed in addition to alignment marks 22 for aligning.

As the dummy pattern 21, patterns shown in FIGS. 3A to 3D can be considered, for example. In FIGS. 3A to 3D, black portions indicate grooves, that is, concave portions used as buffer (liquid storage) areas to absorb the imprint material 11.

Then, as shown in the cross sectional view of FIG. 4, the alignment process and press (contact) process are performed by use of the to-be-processed substrate 10 shown in FIG. 1 and the template 20 shown in FIG. 2. In FIG. 4, the surface of the template 20 shown in FIG. 2 on which the pattern is formed is set to face downward and made in contact with the imprint material 11.

As shown in FIG. 4, the imprint material 11 is filled into the grooves of the main pattern 24 and a surplus portion of the imprint material 11 is absorbed by the dummy patterns 21 formed in the dicing area 23. Therefore, the surplus portion of the imprint material 11 does not leak out into an adjacent shot area on the to-be-processed substrate 10.

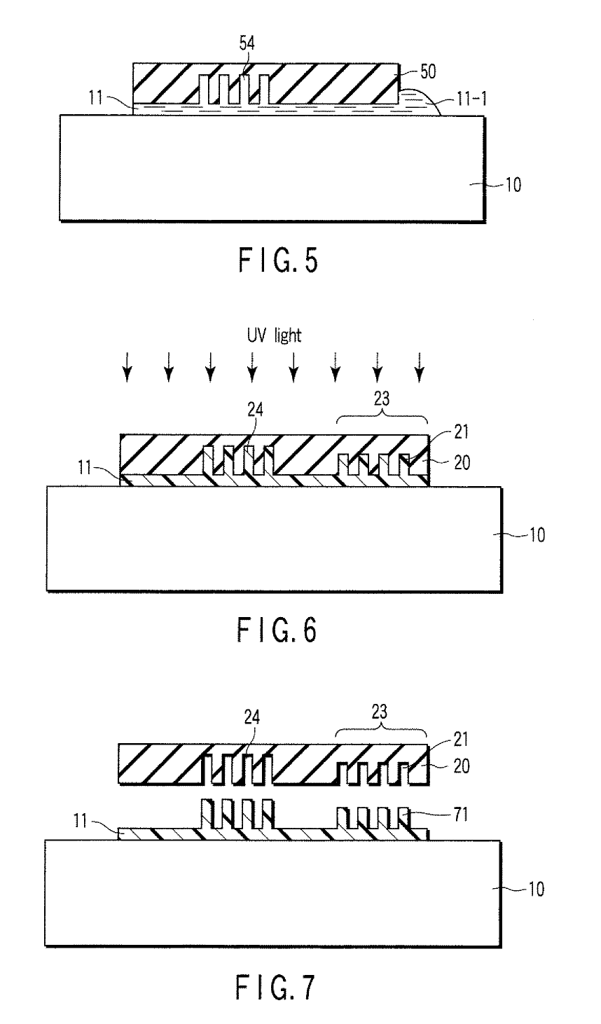

A case wherein the imprinting process is performed by use of a normal template 50 having no dummy patterns 21 as in the conventional case is shown in FIG. 5 for comparison with the case of the present embodiment. As shown in FIG. 5, particularly, if a dispense amount of the imprint material 11 in the end portion of the shot area is surplus, a surplus imprint material 11-1 spills out to the end portion of the template 50. This influences the neighboring shot area and the manufacturing yield is lowered.

However, in the present embodiment, since the dummy patterns 21 absorb the surplus portion of the imprint material 11, leak-out of the surplus imprint material 11 can be prevented as shown in FIG. 4. The dummy pattern 21 is not limited to the patterns shown in FIGS. 3A to 3D and various patterns can be used if the dummy pattern can absorb the surplus imprint material 11.

There is a possibility that patterns corresponding to the dummy patterns 21 are left behind on the dicing area of the to-be-processed substrate 10 after the succeeding steps, but the patterns on the dicing area do not influence the device since they are removed at the last stage.

Further, the dummy pattern 21 is not necessarily formed in the dicing area 23. For example, when a marginal area (space area) is provided in the area in which the main pattern 24 or a device pattern is formed, dummy patterns 21 may be formed in the space area to absorb the surplus portion of the imprint material 11.

After the press step of FIG. 4, UV lights such as i rays are applied to photo-cure the imprint material 11 as shown in FIG. 6. After this, the template separation process is performed as shown in FIG. 7 and then the rinsing process and remaining film removing process are performed (not shown).

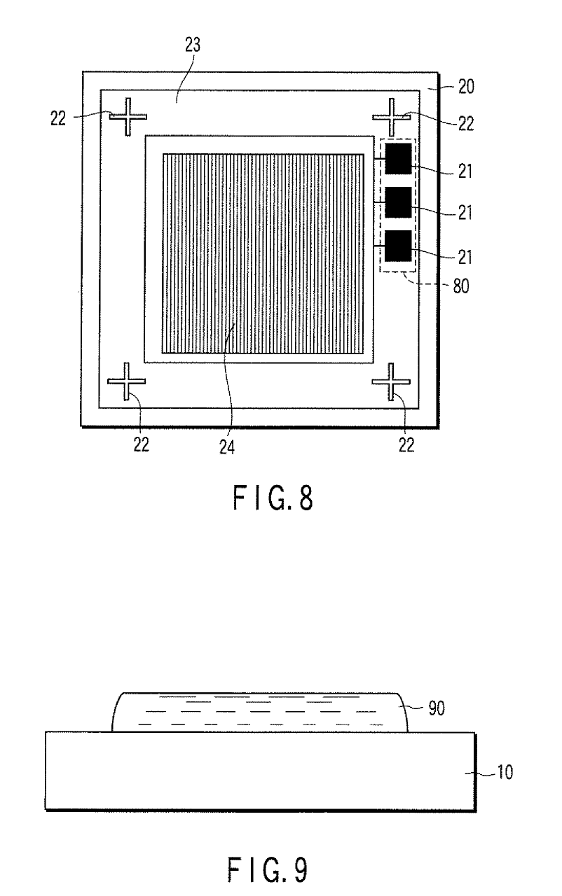

In this case, as shown in FIG. 8, a light shielding film or semitransparent film 80 formed of chrome (Cr) or the like may be previously formed on the surface of the template 20 opposite to the pattern forming surface thereof to cover the dummy patterns 21 of the template 20. Thus, in the UV light application step of FIG. 6, since UV lights applied to the imprint material 11 absorbed by the dummy patterns 21 can be shielded or suppressed, solidification thereof can be prevented. That is, a resin pattern 71 shown in FIG. 7 can be prevented from being formed.

If the light shielding film or semitransparent film 80 is not formed and the resin pattern 71 is formed, then there occurs a possibility that part of the resin pattern 71 may be left behind and filled in the dummy patterns 21 at the template separation time. In this case, If the template 20 shown in FIG. 2 is repeatedly used, there occurs a possibility that the liquid storable amount of the dummy patterns 21 will be reduced. Therefore, the above problem can be solved by forming the light shielding film or semitransparent film 80.

Generally, when the imprint material 11 is coated on the to-be-processed substrate 10 by the ink jet method, the nano-imprinting apparatus previously calculates a necessary amount of imprint material based on pattern information of the template and then performs the coating process. However, in the present embodiment, when a neighboring portion of the dummy patterns 21 other than the main pattern 24 is coated, it is preferable for the nano-imprinting apparatus to have a mechanism which calculates a necessary coating amount for a portion other than the dummy patterns 21.

That is, as the density of the GDS pattern in a portion near the dicing area 23 used to estimate a coating amount at the ink jet coating time, the pattern density in a case where the dummy patterns 21 are not arranged is used. As a result, the surplus portion of the imprint material 11 can be adequately absorbed by the dummy patterns 21.

As described above, in the present embodiment, the dummy patterns (grooves) 21 which can absorb the surplus imprint material 11 are arranged in the dicing area 23 of the template 20 and a coating amount for a portion other than the dummy patterns 21 is estimated at the ink jet coating time.

As a result, the surplus imprint material can be prevented form leaking out to a neighboring chip and the percent defective of chips can be lowered.

### Second Embodiment

A pattern forming method by use of a photo nano-imprinting method according to a second embodiment of this invention is explained below with reference to FIGS. 9 to 12.

First, as shown in FIG. 9, a nano-imprint material 90 which is a photo-setting resin material of liquid of one shot is coated on a to-be-processed substrate 10 by an ink jet method.

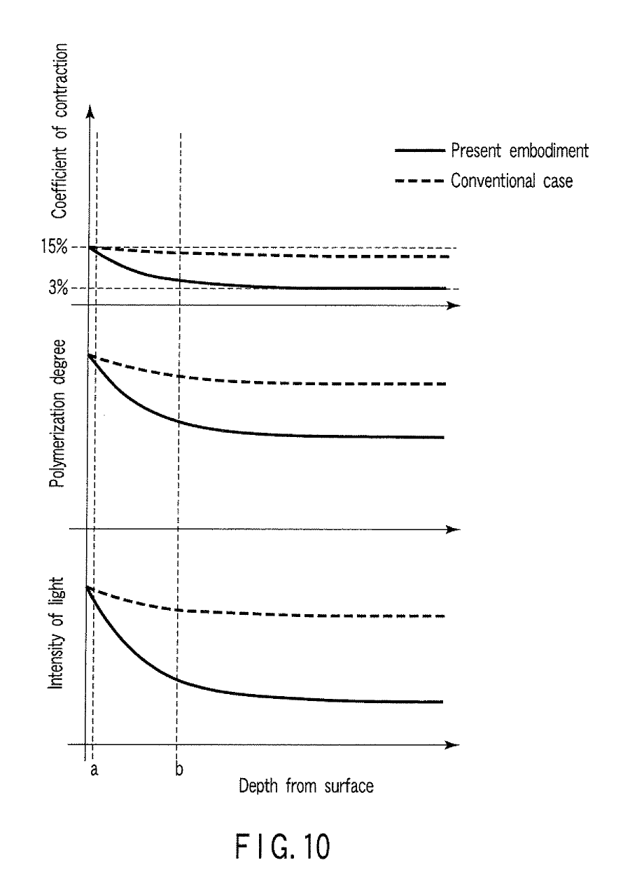

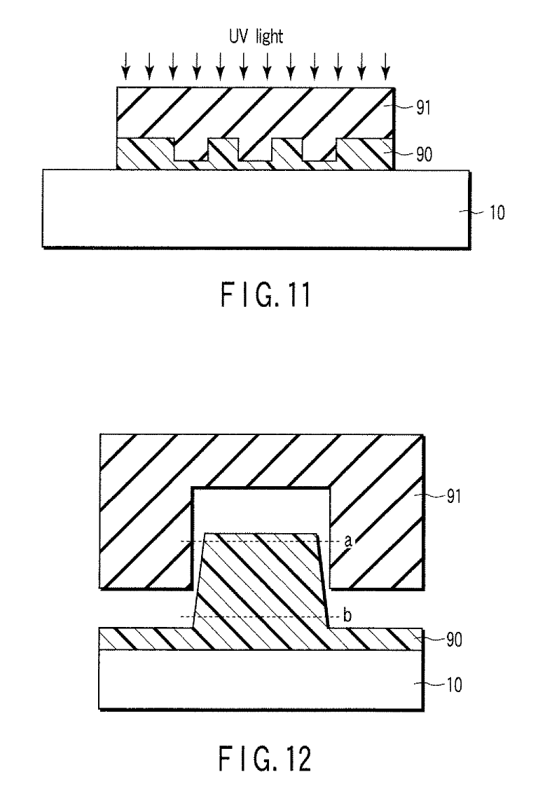

FIG. 10 shows the light intensity, polymerization degree from monomer to polymer and coefficient of contraction at the time of solidification from liquid to resin with respect to the depth from the surface of the photo nano-imprint material in a case where the photo nano-imprint material 90 used in the present embodiment is coated and UV lights are applied thereto together with a case of the conventional nano-imprint material into which a material having a high optical absorption property is not mixed.

Since the photo nano-imprint material 90 has molecular structures having a high absorption property with respect to UV lights, the light intensity is markedly lowered in a deeper portion from the surface in comparison with a case of the conventional nano-imprint material as shown in FIG. 10.

As is understood from FIG. 10, the light intensity in a portion of certain depth from the surface determines the polymerization degree from monomer to polymer in the above depth and the polymerization degree becomes higher as the light intensity becomes higher. Further, the polymerization degree determines the coefficient of contraction obtained when the nano-imprint material is solidified from liquid to resin and the coefficient of contraction becomes larger as the polymerization degree becomes higher.

Therefore, it is possible to realize the coefficient-of-contraction distribution having desired coefficients of contraction in the desired depths, for example, in the depths “a” and “b” of FIG. 10 by controlling an amount of functional groups (molecular structures) of a high optical absorption property contained at the synthesizing time of the nano-imprint material 90. That is, it is possible to change the coefficients of contraction by UV photo-setting in the upper portion and bottom portion of the resin pattern.

The state attained by performing the template mold releasing process after the press process and UV light application process are performed as shown in FIG. 11 by use of the nano-imprint material 90 whose composition is thus controlled is shown in the cross sectional view of FIG. 12. FIG. 12 shows the state of a neighboring portion of one concave groove of the pattern formed on a template 91. The convex-form portion of a formed resin pattern (formed by solidifying the nano-imprint material) 90 is formed in a tapered form in which the upper portion is narrowed.

The functional groups having a UV light absorption property are connected in a side chain form in the nano-imprint material 90 after curing.

In FIG. 11, UV lights are applied to the template 91 in parallel from above. Therefore, the intensity of light applied to the upper portion (that is, the bottom portion of the groove of the template 91 before the template separation process) of the convex pattern of the resin pattern 90 of FIG. 12 becomes higher than the intensity of light applied to the bottom portion (that is, the opening portion of the groove of the template 91 before the template separation process) of the convex pattern. As a result, the contraction amount of the imprint material 90 becomes large in the upper portion of the convex pattern and small in the bottom portion of the convex pattern. More specifically, the coefficients of contraction in the positions of the depths “a” and “b” from the upper surface of the convex pattern are set to values shown in FIG. 10.

Therefore, as is understood from FIG. 12, a gap corresponding to the contraction amount is formed with respect to the template 91 in the upper portion of the convex pattern after photo-setting, but a gap formed in the bottom portion of the convex pattern becomes smaller than the above gap.

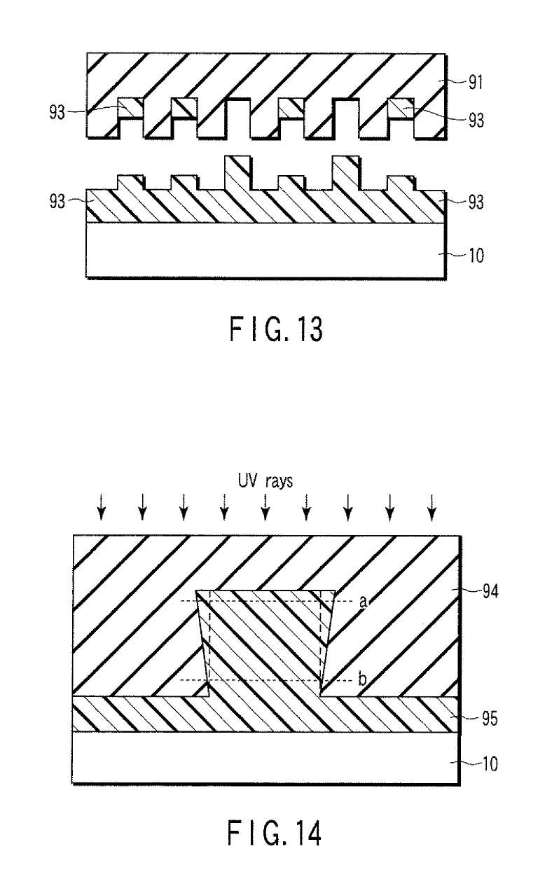

If the conventional nano-imprint material is used, the coefficient of contraction does not much depend on the depth from the surface as shown in FIG. 10. That is, there is no big difference between the coefficients of contraction in a portion near the surface and a portion deeper from the surface. Therefore, in the template separation process after a resist pattern having a high aspect ratio is formed, there occurs a possibility that faults of cutting off an imprint material 93 at the template separation time will occur as shown in FIG. 13.

However, if the template separation process is performed as shown in FIG. 12 by use of the imprint material 90 having the functional groups with the UV light absorption property in the present embodiment, friction at the template separation time becomes small by the effect of the gap formed on the upper portion of the convex pattern and faults will not occur. Therefore, it becomes possible to form the pattern with a high aspect ratio without causing faults and form a resist pattern of large film thickness with high precision.

### Third Embodiment

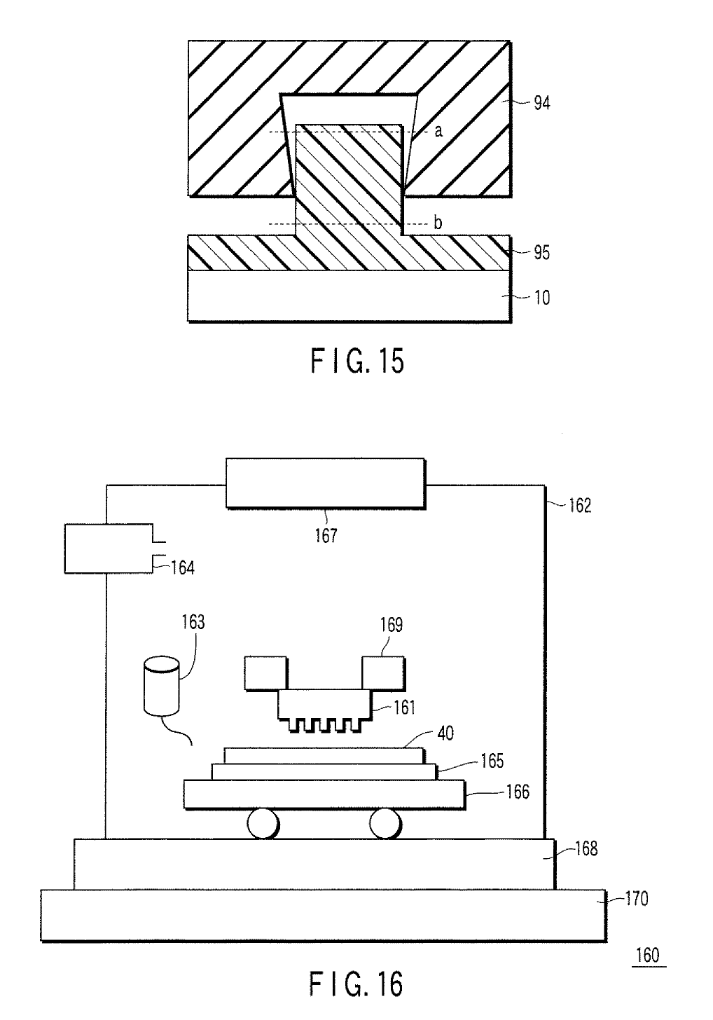

A pattern forming method by use of a photo nano-imprinting method according to a third embodiment of this invention is explained below with reference to FIGS. 14 and 15.

Also, in the present embodiment, like the second embodiment, a nano-imprint material with functional groups having a UV light absorption property which has the characteristic shown in FIG. 10 is used.

In the present embodiment, as shown in FIG. 14, a template 94 on which a pattern having a groove formed with a cross section in a reversely tapered form is formed is used. For example, the reversely tapered form can be attained by controlling bias voltage or controlling the pressure of chlorofluorocarbons (CFCs) gas used as an atmosphere in the plasma etching process.

FIG. 14 is a cross sectional view showing the state of a neighboring portion of one concave-form groove of a pattern formed on the template 94 when UV lights are applied after the pressing process.

In FIG. 14, since UV lights are applied to the template 94 in parallel from above, the intensity of light applied to the upper portion of a convex pattern of an imprint material 95 is higher than the intensity of light applied to the bottom portion of the convex pattern like the second embodiment.

Therefore, as indicated by the form of the imprint material 95 after photo-setting as indicated by broken lines of FIG. 14, the contraction amount of the imprint material 95 by application of UV lights is large in the upper portion of the convex pattern and small in the bottom portion of the convex pattern. That is, the front end portion of the reversely tapered form is more contracted. More specifically, the coefficients of contraction in the positions of the depths “a” and “b” from the upper surface of the convex pattern are set to the values indicated in FIG. 10.

In the present embodiment, the characteristic in which the convex portion of the imprint material 95 is modified into a reversely tapered form by photo-setting is previously and quantitatively measured and the groove of the template 94 is designed and formed in a reversely tapered form to cancel the above characteristic.

Therefore, as shown in FIG. 15 which shows the template separation process, a gap is formed with respect to the template 94 and, at the same time, the form of a resin pattern (formed by solidifying the nano-imprint material) 95 can be formed in substantially a rectangular form or in a slightly tapered form.

The coefficient of contraction in the bottom portion of the convex pattern of the imprint material 95 is markedly lowered in comparison with a case where the conventional imprint material is used as shown in FIG. 10. Therefore, a resist pattern in which a dimensional (CD) variation with respect to the opening width of the groove of the pattern formed on the template 94 is suppressed to minimum can be formed.

Like the second embodiment, in the present embodiment, friction at the template separation time becomes small by the effect of the gap formed in the upper portion of the convex pattern and faults shown in FIG. 13 will not occur. Therefore, it becomes possible to form the pattern with a high aspect ratio without causing faults and form a resist pattern of large film thickness with high precision.

In the above explanation, a case where the groove of the pattern of the template 94 is designed and formed in the reversely tapered form to cancel the characteristic of the nano-imprint material 95 having a specific optical absorption characteristic, polymerization degree characteristic and coefficient-of-contraction characteristic with respect to the depth direction from the surface by providing the functional groups having the UV light absorption property is explained. However, the reverse approach can be made.

That is, when a template 94 on which a pattern formed of a groove in a specified reversely tapered form is formed is provided, a nano-imprint material 95 in which the amount of functional groups having a UV light absorption property is adjusted is formed and used to have a characteristic which cancels the characteristic attained by the above form. In this case, the same effect as that of the present embodiment can be attained.

### Fourth Embodiment

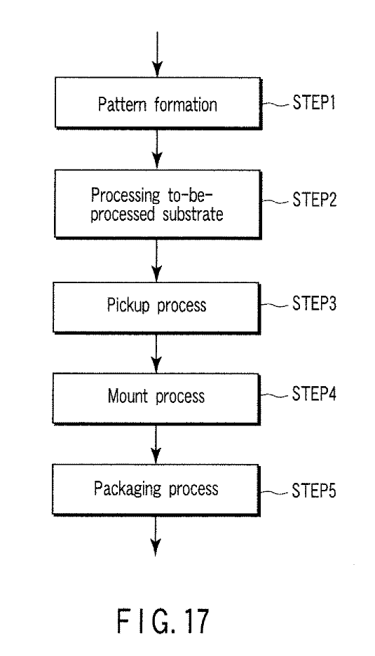

A pattern forming method by use of a photo nano-imprinting method according to a fourth embodiment of this invention is explained below with reference to FIG. 16.

FIG. 16 is a cross sectional view showing the schematic configuration of a nano-imprinting apparatus 160 according to the present embodiment.

In the nano-imprinting apparatus 160 of the present embodiment, a wafer chuck 165 which holds a wafer 40, a movable wafer stage 166 on which the wafer chuck 165 is placed, a template 161, a template holding mechanism 169, an imprint material coating device 163, a pressure device 164 and a UV light source 167 are arranged in a chamber 162. The chamber 162 is set on a stage surface plate 168 and the chamber 162 and stage surface plate 168 are set on a vibration-proof base plate 170. The coating device 163 contains an operating unit which calculates a necessary coating amount for a portion other than a dummy pattern when a neighboring portion of the dummy pattern other than a main pattern is coated. As the density of a GDS pattern near the dicing area used to estimate the coating amount, the pattern density set when the dummy pattern is not arranged is used.

Next, the procedure for transferring a pattern having a concavo-convex surface on the template 161 onto the wafer 40 by use of the nano-imprinting apparatus 160 is explained below.

First, the wafer 40 is placed on the wafer chuck 165 in the chamber 162.

Then, the pressure in the chamber 162 is raised to pressure higher than the atmospheric pressure by use of the pressure device 164. In the present embodiment, the pressure is set to 1.5 atm, for example.

After this, the wafer stage 166 is moved and the wafer 40 is moved below the imprint material coating device 163. Then, the imprint material is coated on the wafer 40 by use of the ink jet system (not shown). The imprinting mechanism of the nano-imprinting apparatus 160 is formed of a step & repeat system, that is, a system of moving the wafer 40 each time the imprinting process of one shot is performed, and therefore, an imprint material of one shot is coated.

For example, the process of coating the imprint material by the ink jet system is performed by causing a nozzle section having a plurality of coating nozzles arranged in a row to scan the coating area. Therefore, a difference occurs between leaving times after the coating process, that is, times until curing by application of UV lights in the first coated area and last coated area.

In the conventional nano-imprinting apparatus, the time difference corresponds to a difference in the volatile amount of the imprint material and causes a variation in the film thickness of the resist pattern in the shot surface and in the wafer surface after imprinting.

However, in the nano-imprinting apparatus of the present embodiment, volatility of the imprint material can be suppressed by setting the pressure in the chamber higher than the atmospheric pressure and a problem of causing a variation in the film thickness can be solved.

After the imprint material of one shot is coated, the wafer 40 is moved below the template 161, the template 161 is brought into contact with the imprint material on the wafer 40 and the UV light source 167 applies UV lights in this state. The light application amount at this time is 20 mJ/cm², for example.

Then, the template 161 is separated from the wafer 40 (template separation process) and a pattern transferred onto the imprint material is obtained.

Next, the above step (next shot) is repeatedly performed with respect to a next chip.

In this case, it is of course possible to coat an imprint material by the spin coat system and, in this case, the imprint material coating device 163 is not necessarily arranged in the chamber.

An imprint material before application of UV lights is not so-called polymer and a problem that the volatility thereof is relatively high occurs. However, in the present embodiment, all of the processes of coating the imprint material, setting the wafer in contact with the template and applying UV lights performed while the imprint material is set in a volatile state before photo-setting are performed in the atmosphere of pressure higher than the atmospheric pressure, that is, in the positive pressure environment.

Thus, the volatile amount of the imprint material can be suppressed low. As a result, the uniformity of the remaining film of the imprint material can be enhanced and the uniformity of the dimension in the shot surface and wafer surface can be enhanced.

### Fifth Embodiment

Next, a method of manufacturing a semiconductor device according to the embodiments of the pattern forming method is explained below with reference to FIG. 17.

FIG. 17 is a flowchart explaining manufacturing method of the semiconductor device according to a fifth embodiment of this invention.

After performing pattern formation according to the methods of above-mentioned embodiments (STEP1), processing the to-be-processed substrate (STEP2) by using the resist pattern as a mask. As the to-be-processed substrate, a silicon substrate itself can be used, or a substrate on which a mask formed of an organic film, or an inter-level insulating film such as a silicon oxide film, or low-k (low permittivity) film, or metal layer for forming an interconnection and electrode, or polysilicon layer for gate electrode is formed can be used.

Then, performing etching by using the resist pattern as a mask, thereby patterning the films and the layers, or ion-implant an impurity into to-be-processed substrate, thereby forming impurity diffusion layers, for example.

Then, the same procedures as in the known semiconductor device manufacturing method are executed. Mounting processes such as a semiconductor chip pickup process (STEP3), a mount process to a lead frame or TAB tape (STEP4), and a packaging process (STEP5) are executed, thereby completing a semiconductor device.

As described above, according to one aspect of this invention, a pattern forming template capable of preventing leakage of a surplus imprint material to neighboring chips, and a pattern forming method capable of forming a resist pattern of large film thickness with high precision can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming template used in a nano-imprinting method for transferring a pattern of a device pattern formation having concave and convex portions onto an imprint material layer formed of liquid having a photo-setting property and coated on a to-be-processed substrate by applying light to a surface of the template on which the pattern is not formed from above the surface to cure the imprint material layer while a surface of the template on which the pattern is formed is kept in contact with the imprint material layer, comprising:
a dummy groove which is different from the pattern.

2. The pattern forming template according to claim 1, wherein the dummy groove is configured to absorb the liquid which overflow into an outside of the template.

3. The pattern forming template according to claim 1, wherein the imprint material layer is formed of liquid of an organic material which has functional groups having a UV light absorption property and in which the functional groups are connected in a side chain form after polymerization by application of UV lights.

4. The pattern forming template according to claim 1, wherein the imprint material layer is cured into resin by applying UV lights thereto.

5. The pattern forming template according to claim 1, further comprising one of a light shielding film and semitransparent film which is formed on the surface on which the pattern is not formed and covers the dummy groove.

6. The pattern forming template according to claim 1, wherein the dummy groove is arranged in a dicing area corresponding to a marginal portion for cutting-off of a chip.

7. The pattern forming template according to claim 1, wherein the dummy groove is arranged in a space area of an area in which the pattern is formed.

8. The pattern forming template according to is claim 1, wherein a cross sectional form of the dummy groove is formed in a reversely tapered form in which the dummy groove becomes wider in a direction from an opening surface of the groove towards a bottom surface thereof.

9. The pattern forming template according to claim 1, wherein the pattern is a concavo-convex pattern formed on a quartz substrate.

10. A pattern forming method comprising:
coating an imprint material layer formed of liquid having a photo-setting property by application of UV lights on a to-be-processed substrate,
making the coated liquid in contact with a template on which a pattern of a device pattern formation having concave and convex portions and a dummy groove which is different from the pattern are formed, and
applying UV lights to a surface of the template on which the pattern is not formed from above the surface to cure the liquid into resin and transferring the pattern onto the resin.

11. The pattern forming method according to claim 10, wherein the liquid is a photo nano-imprinting material.

12. The pattern forming method according to claim 11, wherein the coating is coating the photo nano-imprinting material by use of an ink jet method.

13. The pattern forming method according to claim 10, wherein the imprint material layer is formed of liquid of an organic material which has functional groups having a UV light absorption property and in which the functional groups are connected in a side chain form after polymerization by application of UV lights.

14. The pattern forming method according to claim 10, wherein the dummy groove is configured to absorb the liquid which overflow into an outside of the template.

15. The pattern forming method according to claim 10, wherein the to-be-processed substrate includes one of a silicon substrate, a substrate having a silicon oxide film formed on a silicon substrate, a substrate having an inter-level insulating film formed on a silicon substrate and a substrate having a mask of an organic film formed on a silicon substrate.

16. The pattern forming method according to claim 10, wherein the template is obtained by forming a concavo-convex pattern on a quartz substrate by plasma etching.

17. The pattern forming method according to claim 10, further comprising mold releasing the template, rinsing and removing a remaining film after the transferring.

18. A method of manufacturing a semiconductor device comprising:
coating an imprint material formed of liquid having a photo-setting property on the to-be-processed substrate,
making the coated liquid in contact with a template on which a pattern of a device pattern formation having concave and convex portions and a dummy groove which is different from the pattern are formed,
applying light to a surface of the template on which the pattern is not formed from above the surface while the template is kept in contact with the imprint material,
mold releasing and rinsing the template, and
processing the to-be-processed substrate by using the pattern of the device pattern formation as a mask.

19. The method according to claim 18, further comprising applying a pressure set higher than atmospheric pressure at an imprint material coating time, at a time of making the template in contact with the imprint material and at a light application time.
